(19) United States
(12) Patent Application Publication
(10) Pub. No.: US 2008/0074122 A1
(43) Pub. Date: Mar. 27, 2008

(54) LINE ANALYZER WITH AUTOMATIC PAIR COMBINATION SEQUENCING

(76) Inventors: Bruce R. Barsumian, Cookeville, TN (US); Thomas H. Jones, Cookeville, TN (US)

Correspondence Address: HORNKOHL LAW FIRM, P.O. BOX 210584, NASHVILLE, TN, 37221, US

(21) Appl. No.: 11/840,843

(22) Filed: Aug. 17, 2007

Related U.S. Application Data
(63) Continuation-in-part of application No. 11/715,020, filed on Mar. 7, 2007.
Application No. 11/715,020 is a division of application No. 11/266,538, filed on Nov. 3, 2005, now Pat. No. 7,212,008.
(62) Division of application No. 11/782,636, filed on Jul. 25, 2007.

(51) Int. Cl. G01R 27/28

(52) U.S. Cl. 324/612

(57) ABSTRACT

A line analyzer for detecting line anomalies that may be indicative of electronic tape or other surveillance related electronics coupled to a wire pair in a multiple conductor cable utilizes a switching matrix to identify possible pairings of the conductors and instruct the analyzer to selectively couple to each of the identified conductor pairings. Tests such as non-linear junction detection and frequency or time domain reflectometry operations are automatically performed on each of the wire pairs by the analyzer. The analyzer can automatically identify balanced pairs and limit the testing to the identified balanced pairs to minimize the time required for testing if desired. The results are then mathematically and graphically compared to identify wires having line anomalies. The tests can be performed over time intervals to locate transient anomalies.

### CROSS-REFERENCE TO RELATED APPLICATIONS

The present application is a continuation-in-part of, and claims priority from, co-pending U.S. patent application Ser. No. 11/266,020 filed Mar. 3, 2007 which is a divisional of U.S. patent application Ser. No. 11/266,538 filed Nov. 3, 2005 and U.S. patent application Ser. No. 11/782,636 filed Jul. 25, 2007.

### STATEMENT REGARDING FEDERALLY SPONSORED RESEARCH OR DEVELOPMENT

Not Applicable.

### REFERENCE TO SEQUENCE LISTING OR COMPUTER PROGRAM LISTING APPENDIX

Not Applicable.

### FIELD OF THE INVENTION

The present invention is directed generally toward a line analyzer that has automated line evaluation software and circuitry that sequences through possible line pair combinations in a multiple conductor cable.

### BACKGROUND OF THE INVENTION

Line analyzers have previously been used to detect line parameters and couplings. These analyzers are typically coupled to a wire or wire pair being tested. A set of line parameters are then determined based upon the line's response to the various tests. To test a second line, the line analyzer is then coupled to the next line to be tested and the test procedure repeated. Often, a communication wire being tested has multiple wire pairs. To test a particular pair, the user must manually configure the analyzer to perform the desired test on the selected pair. The user must also manually keep up with which wire pair combinations have been tested. This becomes exponentially more complex as the number of wires increases. Most modern buildings are currently being wired using 8 conductor cable which results in 28 possible wiring combinations (1:2, 1:3, 1:4, 1:5, 1:6, 1:7:, 1:8, 2:3, 2:4, 2:5, 2:6, 2:7, 2:8, 3:4, 3:5, 3:6, 3:7, 3:8, 4:5, 4:6, 4:7, 4:8, 5:6, 5:7, 5:8, 6:7, 6:8, 7:8). In certain situations, a standardized set of tests will be performed on each pair combination within the multiple conductor cable. For example, when searching for concealed electronics coupled to a multiple conductor cable, it is necessary to manually examine each conductor pair combination in the cable to determine if any surreptitious electronics are coupled to any of the wire pair combinations. Reconfiguring the analyzer for each test is time consuming and increases the likelihood that an error will occur in carrying out the test procedure. A further complicating factor is the enormous number of communications lines that may exist in a location or system to be examined. Therefore, what is needed is an improved method and device for testing multiple conductor cables.

### BRIEF SUMMARY OF THE INVENTION

An embodiment of the present invention is directed toward a method of identifying line anomalies in a multiple conductor cable with a line analyzer. In accordance with the method, a switching matrix is determined that specifies a plurality of wire pair combinations and switching instructions for automatically coupling the line analyzer to each of the plurality of wire pair combinations. A test is performed on each of the wire pair combinations specified by the switching matrix to obtain test data for each pairing combination and between each conductor and earth ground. Alternatively, any balanced wire pairs in the wire pairs specified by the switching matrix can be automatically identified and the test only performed on the balanced wire pairs. Typically, balanced wire pairs consist of conductors that are twisted together to maintain a desired transmission line impedance to minimize signal loss and noise. The tests may include, but are not limited to, multi-meter type measurements such at voltage, current, resistance, and capacitance; AC voltage level, audio and video content; non-linear junction detection; RF detection; and frequency and time domain reflectometry operations. A table or graph of the test data is then displayed for use in identifying any line anomalies. The test data is also mathematically compared by the analyzer to further aid in identifying line anomalies.

An alternative embodiment of the present invention is directed toward a device for examining a multiple conductor cable to detect line anomalies. The device includes software or circuitry for determining a set of possible conductor pair combinations for the multiple conductor cable and selectively coupling the device to each pair combination of the conductors in the set of possible conductor pairs. A line test is performed on each pair to obtain test data and a memory is used to store and recall the test data. The device can selectively identify the balanced conductor pairs in the set of conductor pair combinations and limit the test to the balanced pairs. The balanced conductors may be automatically determined by the test results or pre-defined by the user. The device can perform multi-meter type measurements such at voltage, current, resistance, and capacitance; AC voltage level, audio and video content; non-linear junction detection; RF detection; or frequency or time domain reflectometry tests on each of the conductor pair combinations in the set of conductor pairs. A tabular or graphic display simultaneously displays the test data from each pair combination of conductors in the set of conductor pairs. Software mathematically compares test data from each of the conductor pair combinations to identify potentially interesting line anomalies.

Yet another embodiment of the present invention is directed toward a line analyzer for detecting line anomalies on a multiple conductor cable having a plurality of conductors. The line analyzer include pair selection circuitry for automatically identifying possible conductor pairing combinations of the plurality of conductors in the multiple conductor cable. Switching circuitry automatically and sequentially couples the line analyzer to each of the possible conductor pair combinations. Test circuitry performs multi-meter type measurements such as voltage, current, and resistance; audio and video content; non-linear junction; RF detection; and reflectometry tests on each of the possible conductor pairs. The line analyzer includes a tabular and graphic display that simultaneously displays a test data from each of the possible conductor pairs. Balanced pair identification software identifies conductor pairs in the possible conductor pair combinations that are balanced. The line analyzer mathematically compares the test results for each of the possible conductor pairs to identify specified line anomalies.

### BRIEF DESCRIPTION OF THE SEVERAL VIEWS OF THE DRAWINGS

FIG. 1 is a block diagram of a test setup using arrays of reed relays to implement a switching matrix in accordance with an embodiment of the present invention;

FIG. 2 is a flow chart of a method of automatically testing a multiple conductor cable in accordance with an embodiment of the present invention;

FIG. 3 is a block diagram of a software controlled analyzer for automatically testing a multiple conductor cable in accordance with an embodiment of the present invention;

FIG. 4 is an illustration of a graphic output screen for a non-linear junction detection test sequence performed on an eight wire conductor cable in accordance with an embodiment of the present invention;

FIG. 5 is an illustration of a graphic output screen for a RF test sequence performed on an eight wire conductor cable in accordance with an embodiment of the present invention;

FIG. 6 is an illustration of a tabular graphic output screen in accordance with an embodiment of the present invention;

FIG. 7 is a block diagram of balanced pair detection circuit in accordance with an embodiment of the present invention;

FIG. 8 is an illustration of a graphic output screen showing the balanced pairs identified by a balanced pair identification test in accordance with an embodiment of the present invention; and

FIG. 9 is an illustration of a graphic output screen showing the results from a balanced pair identification test performed on a six conductor flat cable in accordance with an embodiment of the present invention.

### DETAILED DESCRIPTION OF THE INVENTION

The present invention is directed toward an improved process for detecting taps, wiring or electronics that may be coupled to a multiple conductor cable. The process can be applied to any type of multiple conductor wiring that is carrying information or power such as data lines, LAN lines, telephone lines, power lines, etc. The present invention is particularly advantageous over the prior are with respect to automatically analyzing communication cables with multiple conductors to detect any surreptitious electronics coupled to a non-standard conductive wire pair of the cable or coupled to any of the conductors and an earth ground.

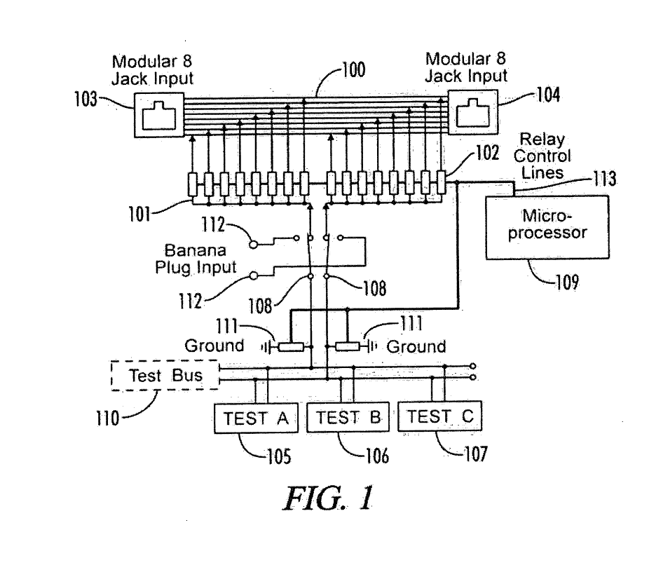

FIG. 1 is a block diagram of a test setup using arrays of reed relays to implement a switching matrix in accordance with an embodiment of the present invention. As shown in FIG. 1, two arrays 101 and 102 of eight reed relays each are connected to an eight conductor bus 100 which is in turn coupled to an eight conductor modular input 103 and output 104. During a test sequence, the modular inputs 103 and outputs 104 may be connected to communication equipment such as phones or switches, or an un-terminated raw cable. The reed relays 101 and 102 are used to selectively interface various pieces of test equipment 105, 106 and 107 to conductors of the eight conductor bus 100 which is connected to the modular input 103 and output 104. One reed relay of each reed relay array 101 and 102 is electrically connected to each of the eight conductors of the bus 100 coupled to the modular input 103 and output 104. The reed relays 101 and 102 are controlled by a microprocessor 109 through relay control lines 113. By sending the correct control codes to the reed relays 101 and 102, selected conductors 100 of the modular input 103 and output 104 can be automatically coupled to the test equipment 105, 106 and 107 by the microprocessor 109 to implement a switching matrix as described in more detail below. Electron switches such as transistors or field effect transistors may be used instead of electro-mechanical reed relays 101 and 102 in specialized applications. However, reed relays 101 and 102 are strongly preferred due to the fact that transistor type switches will add additional non-linear line impedance characteristics which tend to be unsuitable for communications line testing.

A set of switches 108, also under the control of the microprocessor 109, and a test bus 110 selectively connect the appropriate piece of test equipment 105, 106 and 107 to the appropriate conductors of the bus 100 selected by the reed relays 101 and 102. A pair of earth ground connections 111 is provided so that the microprocessor 109 can selectively pair a conductor 100 with an earth ground 111 using the reed relays 101 and 102. A pair of banana plug inputs 112 provides the test technician with additional access to the test inputs selected by the microprocessor 109 through the use of the reed relays 101 and 102. While the cable input 103 and output 104 shown in FIG. 1 have eight conductors, the present invention can be readily adapted to test cables having any number of conductors and any type of input/output connectors.

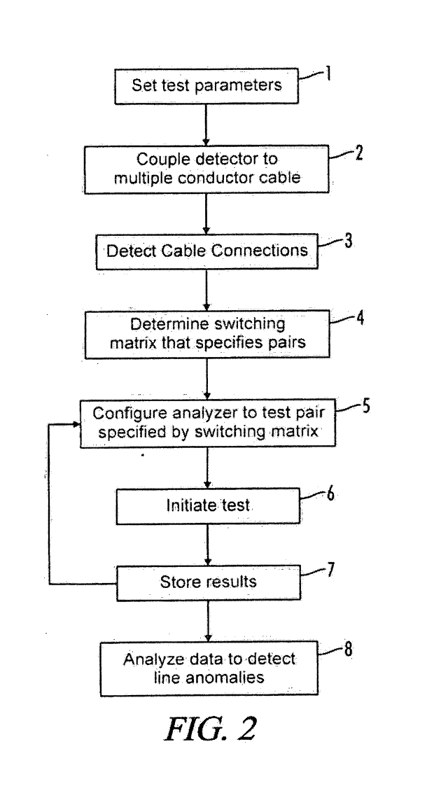

Referring now to FIG. 2, a flow chart of a method of automatically testing a multiple conductor cable with a line analyzer in accordance with an embodiment of the present invention is shown. The method begins with the setting of the test parameters in step 1. These parameters represent the tests to be performed on each wire pair and any required test settings. For example, each wire pair may be subjected to a voltage, capacitance, resistance, line current, audio, video, RF, non-linear junction and reflectometry tests as discussed in more detail herein and the line analyzer settings required for the tests are specified by the test parameters.

In step 2, the analyzer is coupled to the multiple conductor cable being tested. The analyzer preferably has a modular input that is capable of coupling to a variety of different cable types having multiple conductors. The analyzer then determines the number of wires in the cable connected to the analyzer in step 3. This can be automatically accomplished by examining the impedance or capacitance of each analyzer input.

A switching matrix is used in step 4 to determine all of the possible wire pair combinations of the wires in the cable, and between each possible conductor and earth ground. For example, if a cable has 8 wires, the typical active wiring pairs are as follows: 4:5 is typically the primary pair; 3:6 is the secondary pair; 1:2 is an auxiliary pair and 7:9 is an auxiliary pair. Although these are the commonly used conductor pairs, it is important to note that these 8 conductors can actually form 28 different possible wire pair combinations. These possible wire pairings are 1:2, 1:3, 1:4, 1:5, 1:6, 1:7, 1:8, 2:4, 2:5, 2:6, 2:7, 2:8, 3:4, 3:5, 3:6, 3:7, 3:8, 4:5, 4:6, 4:7, 4:8, 5:6, 5:7, 5:8, 6:7, 6:8 and 7:8. In addition, each individual conductor may form a pair using an earth ground or other available wiring in the environment. If an earth ground pairing with each of the eight conductors is included, an additional eight earth ground pair combinations will be added to the 28 possible pair combinations listed above. Surveillance devices can certainly be configured to use an odd or unusual combination of wire pairs or an earth ground so a thorough and complete scan of a system preferably tests all of the possible wire pair combinations including coupling each conductor to earth ground. However, a quick scan can simply cover the main default four wire pairs in a common eight conductor transmission line. Such a limited scan will still produce good results due to the fact that, even if an odd combination of pairs is used by a surveillance device, depending on the type of line tap, there may still be noticeable alteration in the line's response for any pair combination that contains one of the wires used by the tap. However, if a user tests a wire pair that contains both conductors used by the tap, the effects of the tap on the test results will be further enhanced.

An embodiment of the present invention preferably has a number of different pair testing options. An “all pairs” testing option utilizes a switching matrix that provides for automatic switching and test measurements for all of the possible wire pair combinations in a multiple wire cable. In the “all pairs” mode, the switching matrix is solely determined by the number of wires to be treated. In a “balanced pairs” mode, a switching matrix is created that instructs the analyzer to only thoroughly test the balanced wire pairs in the cable. In a twisted cable, wires are twisted together in pairs to improve the transmission capabilities of the cable. The pairs that are twisted together are referred to as balanced pairs. Balanced pairs can be automatically identified as discussed below by comparing test data obtained from each wire pair. Alternatively, the user can manually specify the particular wire pairs to test by selecting a “user defined pairs” testing procedure and a matrix is created that will instruct the analyzer to test only the specified pairs.

In step 5, the analyzer is configured to perform the tests indicated by test parameters on the first wire pair specified by the switching matrix. The specified tests are then performed on the pair in step 6. In step 7, the test results are stored in a memory for later analysis and review. The method then proceeds to back to block 5 wherein the line analyzer is automatically configured to test the next wire pair specified by the switching matrix. The method continues until all of the specified wire pair combinations and or additional conductors have been tested. The analyzer then automatically analyzes the wire pair data in block 8 to locate any line anomalies as discussed in more detail herein. To automate the analysis, the wire pairs are preferably classified according to their configurations such that commonly configured pairs can be identified and compared to detect any anomalies.

By utilizing a switching matrix to automatically identify all the possible wire pair combinations for testing and then automatically configuring the line analyzer to test and monitor the identified pairs, the present invention greatly reduces the time and effort required to examine a multiple conductor communication system for line anomalies that may be indicative of a concealed surveillance device or unusual line configuration.

A test sequence is used by the analyzer to identify the series of tests that are to be performed on the selected wire pairs. A number of different tests may be automatically performed on each of the wire pairs as the analyzer switches through the wires pair combinations in the manner specified by the matrix. For example, a test may be divided into on-hook, off-hook, phone disconnected, line isolated and line terminated stages that are set forth in the test sequence. To prevent a potentially damaging or non-practical test, automatic initial test conditions are set for performing the selected tests. For example, a capacitance will not be measured for a pair that is shorted or powered. Also, an automatic ranging function is preferably implemented to ensure that each measurement is meaningful. A record is made of any data that is out of range. For example, if a handset off-hook test is performed with a call in progress, audio should be detected only on the main pair. If audio is detected on another pair, a flag is produced and the data saved Once the line data has been obtained for a particular wire pair, it is saved in memory and the analyzer configured to test the next wire pair specified by the switching matrix.

During the test procedure, each selected wire pair is preferably subjected to frequency (FDR) or time domain reflectometry (TDR) detection analysis to identify taps coupled to the wires. In performing the FDR or TDR tests, a line bias may be applied to pair to enhance the reflectometry response. The multiple traces that result from these tests can be graphically displayed on the analyzer's screen and visually and mathematically compared. They are typically very similar for systems sharing a common configuration and line anomalies will become readily apparent both to the system and the operator. While a full scan is best, line anomalies can often be detected by only testing the balanced pairs. In addition, the reflectometry tests provide an indication of the location of the electronic connection to the wire pair making anomalies all the more apparent.

The automatic line switching and testing is also very beneficial when used in conjunction with non-linear junction detection technology. Non-linear junctions are present in semiconductor electronic components. When subjected to an electrical signal or electromagnetic radiation at a given frequency, a non-linear junction will re-radiate harmonic signals at whole integer multiples of the frequency of the original electrical signal that was applied to the non-linear junction. For example, if a nonlinear junction is radiated with a signal having a frequency of 100 kHz, the non-linear junction will re-radiate signals having frequencies of 200 kHz, 300 kHz, 400 kHz, etc. The 200 kHz frequency is known as, and referred to herein as, the second harmonic, and the 300 kHz frequency is known as the third harmonic.

The non-linear junction detection (NLJD) function is one of the most powerful tests in the test sequence. It is very reliable for determining if there are additional electronics attached to a line and identifying the connection as a series or parallel connection on an automated basis. In addition, when testing a line for an NLJD response, a strong 3^{rd} harmonic response is typically not the result of a corrosive line, but of parallel limiting diodes used in phone taps for high voltage protection. Non-linear junction analysis can also be performed with the line still connected to the switch although a preliminary analysis has to be performed to insure that the detected signals are not part of the phone system.

A bias voltage can also be applied to the line by the line analyzer during each appropriate test. This bias voltage is useful to power devices that may be voltage or current activated to produce audio or RF transmissions. Furthermore, semiconductor based non-linear junctions have a response that varies more depending upon the level of DC or AC bias voltage on a line than do non-linear junctions created by corrosive or dissimilar metal junctions. By coupling a variety of different bias voltage to the line under test, the presence of semiconductor based non-linear junctions can be detected by their changing responses to the test signal. The bias voltage is preferably varied in amplitude or polarity to detect changes in the non-linear junction's response that are indicative of whether or not semiconductor based non-linear junctions are present. This is particularly useful in determining if any detected couplings are indicative of a concealed surveillance device.

The wire switching and testing stages listed above result in large amounts of test data that is automatically recorded and analyzed by the analyzer software as further discussed.

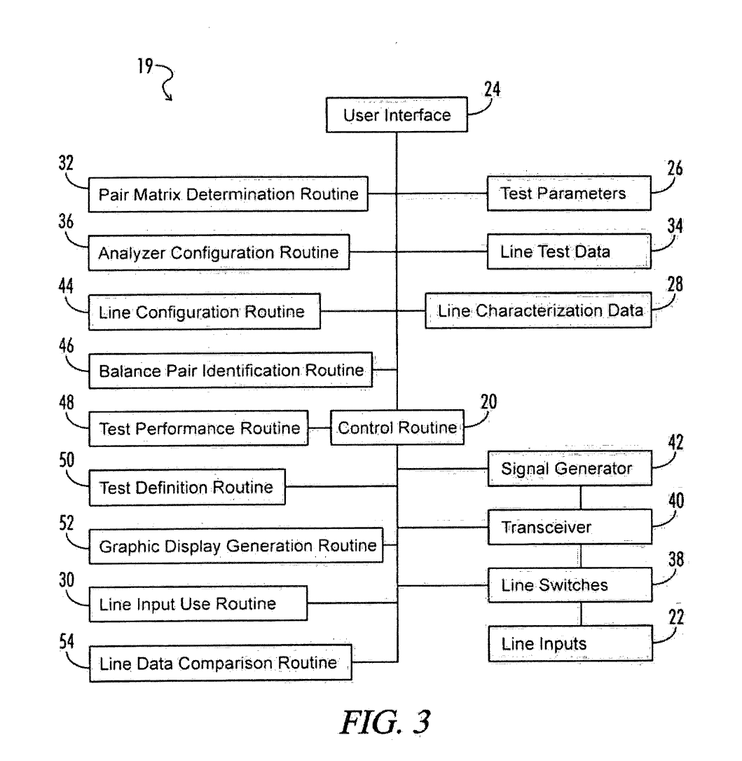

FIG. 3 is a block diagram of a software controlled line analyzer 19 for automatically testing a multiple conductor cable in accordance with an embodiment of the present invention. The analyzer 19 is controlled by a control routine 20 that receives user instructions concerning tests to be performed through a user interface 24. The instructions and settings for performing the tests are stored in a test parameter database 26 or specified by a user through a test definition routine 50. The control routine 20 is coupled to the multiple communication lines being tested through line inputs 22. In an eight conductor communication cable, eight wires are coupled into a single cable that is terminated in a connector. A line analyzer constructed in accordance with an embodiment of the present invention has modular connectors for line inputs 22 that allow it to be coupled to a 2, 4, 6 or 8 wire connector that accommodates most types of common communication cables. A patch cable or adapter can be used to mate uncommon connector types to the line analyzer inputs 22.

The tests utilize line characterization data 28 that is stored in memory and determined by testing or entered by a user. The line characterization data 28 may include the location and time of the test as well as the line property and system configuration data. A line input use routine 30 preferably examines the input lines and determines which of the analyzer's inputs are actually coupled to a wire. This minimizes the time required to run through a test procedure by eliminating unnecessary testing and processing.

A pair matrix determination routine 32 is used to determine a switching matrix that specifies the line pairs in the cable to test. The available wires define the maximum number of wire pairs that can be analyzed. The switching matrix can be further limited by defining additional pair selection criteria concerning the particular cable being tested to minimize the required amount of testing. The pair selection criteria are used to select pairs based upon additional information such as specific targets or locations within a test job that are identified by address, building number, building floor, office number etc. The analyzer 19 can also be adapted to test each pair for a voltage level and capacitance to verify the active and/or balanced pairs and the switching matrix limited accordingly. In the examples set forth, all 8 conductors exist in the phone cord. However, if a 4-conductor conductor phone cord is being tested, then the 1, 2, 7, and 8 wires are preferably excluded from the analysis to reduce unnecessary testing.

A balanced pair identification routine 46 is used to identify any balanced pairs. Capacitance measurements may vary greatly, because capacitive coupling varies greatly, between unbalanced pairs. However, balanced pairs should have very consistent capacitance measurements. When planning to test a telephone line, it is important to be able to identify the balanced pair combinations since, in some testing situations, it is sufficient to only test the balanced pairs and to not test all of the odd pair combinations. The balanced pair identification routine 46 includes test functions, described in more detail below, that assist in identifying which pair combinations are the balanced pairs such as a line impedance test that measures the coupling between the balanced line pairs.

Once a switching matrix has been determined, an analyzer configuration routine 36 is used to configure the analyzer 19 to perform the selected tests on the wire pair combination specified by the switching matrix. A set of hardware or software line switches 38 is used to automatically couple the analyzer's transceiver 40 to the selected wire pair combination. A signal generator 42 generates any test signals specified by the test parameters 26 in response to test instructions received from the test performance routine 48. The test performance routine 48 instructs the analyzer to perform any specified tests on each wire pair which may include but are not limited to analog and digital audio analysis, broadband RF and signal activity level. The line analyzer 19 has save and recall functions that allow any collected line test data 34 or line characterization data 28 to be stored and later recalled for review or comparison.

A line characterization routine 44 is used to characterize the wire pairs being tested. The lines may be characterized based upon user entered data or upon measurements automatically acquired from the wire pair under test. The line characterization data 28, such as voltage, capacitance, impedance, etc., is stored for later reference. To reduce the likelihood of detection, a test may be cancelled if the line characterization routine 44 detects a high DC voltage that indicates the line may be in use.

A graphic display is preferably provided through the user interface 24 that indicates if any concealed or unexpected electronics exist based on a consistent response from pair to pair. A graphic display generation routine 52 generates the graphics based upon the line test data 34. The present invention anticipates that electronics exist on the pairs under test, often even on non-active pairs. However, differences in the electronic response of similarly situated lines from one pair to the next or from one phone to the next may be indicative of a concealed electronic device since similarly configured lines should produce similar responses and line signatures.

A line comparison routine 54 compares the data acquired from multiple lines to identify line anomalies. Line anomalies may be detected in a variety of different manners. During each test stage the analyzer 19 preferably checks to see if any test parameters are exceeded that may be indicative of a line anomaly. For example, in an on-hook test, no analog or digital audio should exist on any pair. The analyzer makes a record of the test results and stores the test data in its memory. Several types of comparisons can be made to help determine if a concealed electronic device is attached to a line. For example, comparisons may be made between conductor pairs within the same cable. In addition, comparisons can be made between the same wire pair combination in different cables associated with different phones or phone jacks. Also, standard lines such a phone lines can be compared to stored reference signatures obtained from a similar standard type line to detect the presence of additional unexpected electronics or taps. Comparisons can also be made between the line signatures of a given wire pair within the same cable taken at different measurement times using the stored line test data. This allows a technician to determine if unexpected changes in the line's response have occurred over times that may be indicative of a new connection to the line.

A mathematical approach can be used by the analyzer compare the line test data. The mathematical approach generates mathematical models of the line data for comparison. One such method is to generate polynomial equations to represent each line signature curve. Software can then simply compare the terms of the polynomial equations to mathematically compare the lines. When performing a surveillance sweep, any pair exhibiting an irregular response is a candidate for further inspection to determine the source of the irregularity.

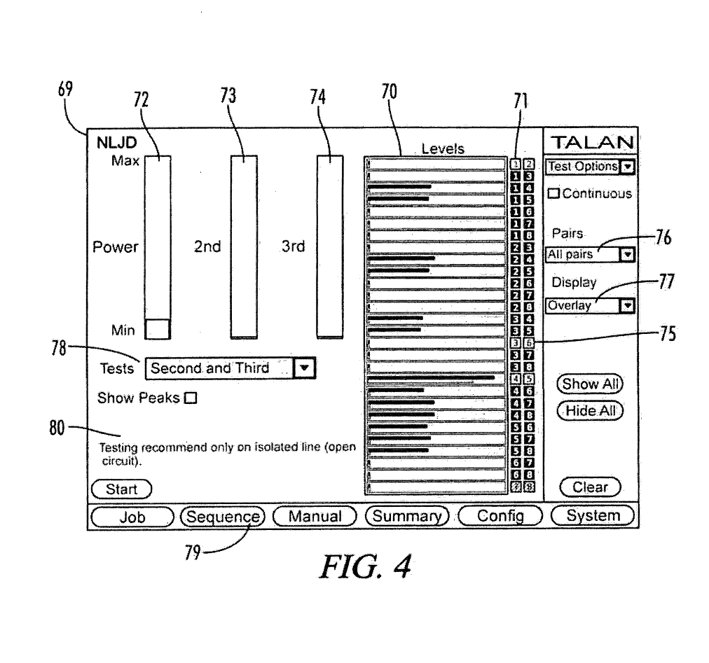

FIG. 4 is an illustration of a graphic output screen 69 for a non-linear junction detection test sequence performed on an eight conductor cable in accordance with an embodiment of the present invention. The screen 69 displays a response level 70 detected for each wire pair 71 in the eight cable conductor. Active pairs 75 are highlighted to help aid the sweep technician in evaluating the test results. Test data, such as the transmit power level 72 and second 73 and third 74 harmonic levels of a non-linear junction test, are also displayed. The pairs to test can be selected from a drop down menu 76. Another drop down menu 77 allows the technician to alter the test data displayed. The tests drop down menu 78 allows the technician to switch the display 69 between the various different tests performed by the analyzer. Table 79 at the bottom of the screen 69 allow for test set up, test sequence, system configuration, job description and summary functions to be accessed. Helpful information in the form of hints and suggestions 80 are displayed to the technician throughout the testing and review procedures.

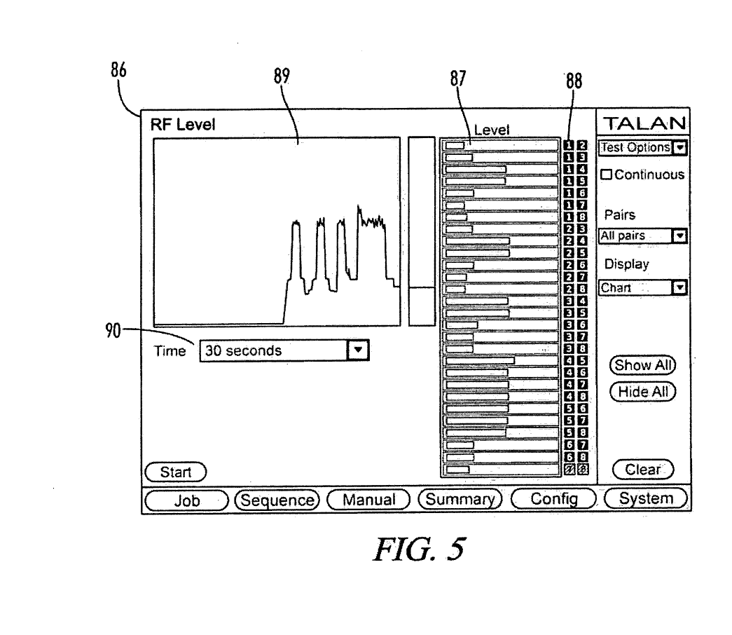

FIG. 5 is a an illustration of a graphic output screen 86 for a RF signal level test sequence performed on an eight wire conductor cable in accordance with an embodiment of the present invention. The screen 86 displays a peak RF level 87 detected for each wire pair 88 in the eight cable conductor and a time plot 89 for a selected pair showing the variations in the RF signal level detected during a selected time range. The time plot function is selected through the drop down menu 90 and the wire pair is selected by clicking on the appropriate wire pair display 88 of the wire pairs specified by the switching matrix. In the example of FIG. 5, the cable that was tested was only a 2-wire system, but an 8 conductor Cat 5 cable was used in the system. Hence, any pair that includes wire 4 or wire 5 results in some signal being detected. Also, in the example of FIG. 5, all wire pairs were tested for general broadband RF energy and all pair combinations containing wire 4 or 5 contain significant RF energy. This is because the wire pair 4:5 in this particular example is active. The data was captured by automatically switching through the wire pairs using a switching matrix as described herein.

The analyzer can preferably display multiple time traces simultaneously. The pair combinations with the strongest bar graphs should be the active pairs. The active pairs are preferably displayed on the test screen in a manner that allows them to be easily identified. It may be useful to capture an RF trace of the main 4:5 pair as well as the other balanced pairs. This can be done by having the analyzer automatically capture these spectrum traces or simply manually selecting the pairs of interest and displaying the spectrum traces simultaneously. Simultaneously displaying the traces allows time dependent anomalies to be more readily identified.

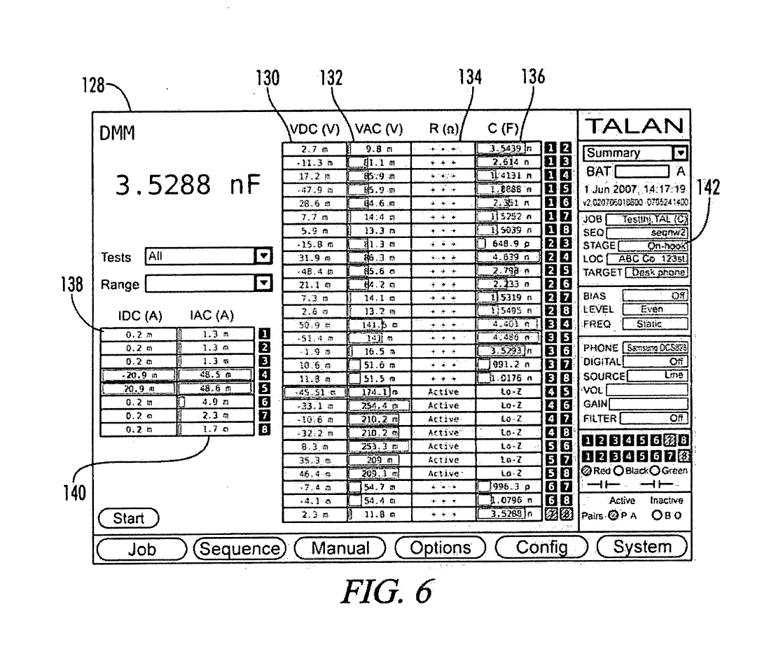

An illustration of a tabular graphic output screen 128 in accordance with an embodiment of the present invention is shown in FIG. 6. The tabular output screen shows the results of multiple digital multi-meter tests such as DC voltage 130, AC voltage 132, resistance 134 and capacitance 136. Individual DC currents 138 and AC currents 140 are also displayed for each individual conductor being checked as part of the automated test procedure. Test summary information 142 is displayed on the right side of the screen. By automatically producing the data shown in FIG. 6, an embodiment of the present invention significantly reduce the time required for a technician to obtain the data shown while reducing the likelihood of an erroneous test.

Within cable testing, especially multi-conductor cable testing, the need to identify commonly used twisted pair combinations that carry electronic information is of great benefit, being that these pairs are the basic data links used to connect two devices for communication. A preferred embodiment of the present invention utilizes an automated process to identify these balanced pair combinations in twisted cables and aid the technician in analyzing wiring in physical structures. Most preferably, the automatic balanced pair identification routine identifies the balanced pairs by measuring each pair's characteristic impedance and determining which pair's characteristic impedance is closest to its designed characteristic impedance. For an example using a multi-conductor twisted cable with any number of conductors, the impedance measured across a given frequency band for two conductors within the cable will result in a relative number. The results of an impedance scan of each two-conductor combination within the cable can then be compared against every other two-conductor combination within the same cable. Balanced pairs will tend to have relative numbers with the highest figure of merit values. The results are preferably normalized prior to the comparison.

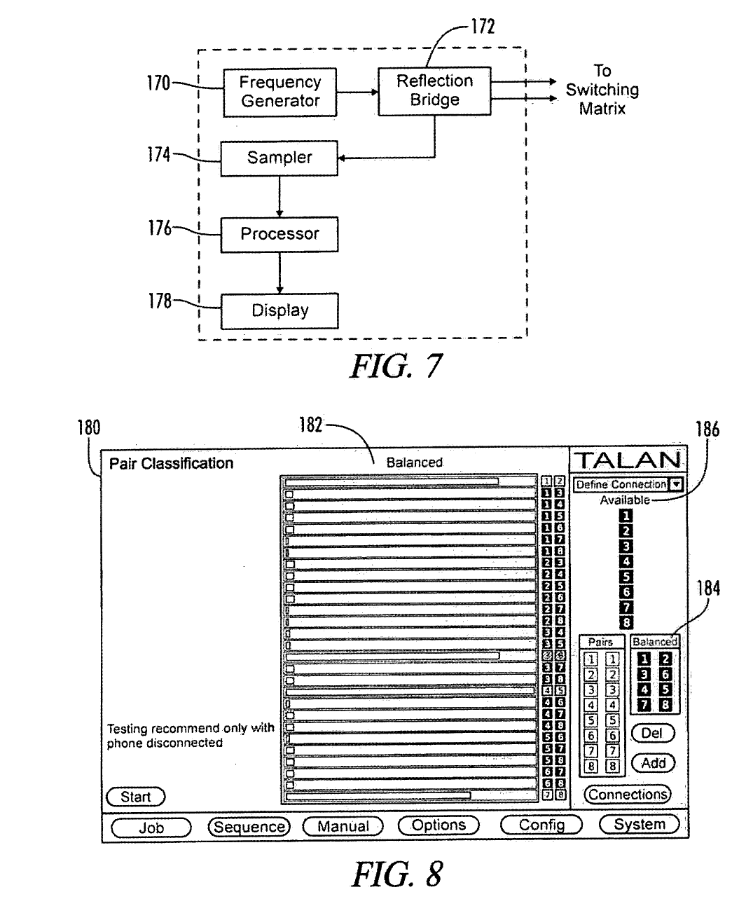

Referring now to FIG. 7, a block diagram of balanced pair detection circuit constructed in accordance with an embodiment of the present invention is shown. The design consists of a frequency generator 170, a balanced reflection bridge 172, a sampler 174, a processor 176 and a display 178. The frequency generator 170 creates a sinusoidal frequency sweep of a given bandwidth in predetermined steps. This sweep is driven into a reflection bridge 172. The reflection bridge 172 compares the impedance between the two conductors to a known impedance value and results in a complex return that is measured by the sampler 174. The measurement is captured from the sampler 174 by a processor 176 at each step of the frequency sweep and evaluated. The processor 176 averages the measurements from across the frequency sweep for each two-conductor combination and stores the result. This averaged measurement is used as an impedance figure of merit that is related to the characteristic impedance of the cable. The impedance figure of merit is based on the electromagnetic coupling between each pair of conductors. In an alternative embodiment, the actual characteristic impedance of the cable may be calculated from the obtained impedance figure of merit. However, in a preferred embodiment, the characteristic impedance is not calculated since it is only the relative value of the data that is important. The balanced pair identification scheme described above is beneficial in that the end results are independent of cable length and of the line termination condition.

The results of a balanced pair test can be graphed in a bar graph format so that a user can visually evaluate the differences between the impedance figures of merit for each pair. An illustration of a graphic output screen 180 that shows the balanced pairs identified by a balanced pair identification test in accordance with an embodiment of the present invention is shown in FIG. 8. The figure of merit 182 is shown on the screen 180 for each pair of conductors in the cable. The balanced pairs 184 can be visually identified by their large figures of merit 182. To further aid the user in identifying the balanced pairs, the figure of merit bar graphs 182 may be scaled to visually enhance the bar graph display 180. While the graphic output screen 180 can be used to allow the user to visually identify the balanced pair combinations, identification of the balanced pairs is preferably done automatically. In FIG. 8, the automatically determined balanced pairs are listed in a column 184 on the right of the screen 180. A second column 186 lists the inputs of the analyzer that are connected to conductors. While the graphic displays discussed are preferred, any type of suitable display can be used.

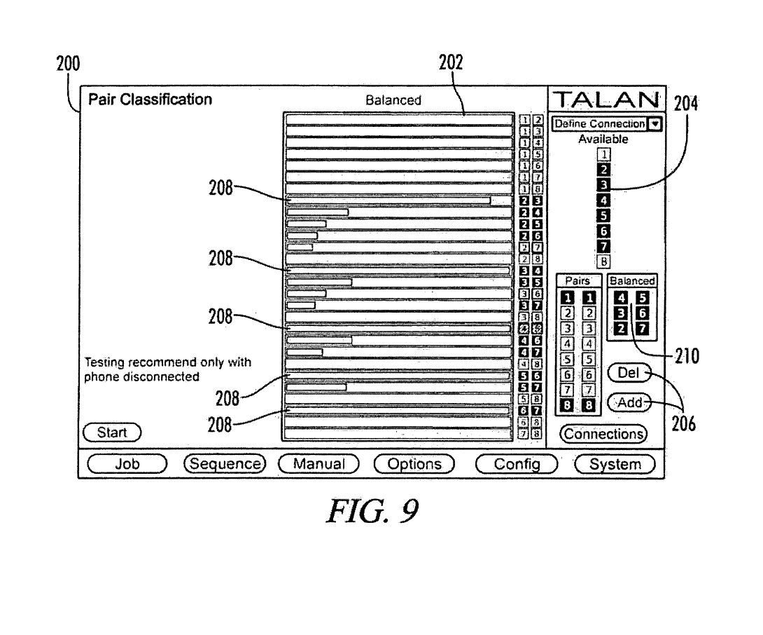

If a multi-conductor cable is flat and has no balanced pairs, the balanced pair test will identify the cable as flat. Referring now to FIG. 9, an illustration of a graphic output screen 200 showing the results from a balanced pair identification test performed on a six conductor flat cable in accordance with an embodiment of the present invention is shown. The cable is identified as having six conductors, and the six conductors listed, in a column 204 on the right of the screen. The value 202 of the figures of merit for each of the conductors is displayed on the screen 200. As can be seen in FIG. 9, adjacent conductors in the cable have high figures of merit 208. This indicates that the cable is a flat cable. In such a situation, the pairs of particular interest in the cable are manually entered by the user using add and delete keys 206. The identified pairs 210 are then displayed on the screen.

Although there have been described particular embodiments of the present invention of a new and useful system for LINE ANALYZER WITH AUTOMATIC PAIR COMBINATION SEQUENCING, it is not intended that such references be construed as limitations upon the scope of this invention except as set forth in the following claims.

What is claimed is:

1. A method for identifying line anomalies in a multiple conductor cable with a line analyzer, said method comprising the steps of:
determining a switching matrix that specifies a plurality of conductor pair combinations and switching instructions for automatically coupling said line analyzer to each of said plurality of conductor pair combinations; and
performing a test on each of said conductor pairings specified by said switching matrix to obtain test data for each pairing.

2. The method of claim 1 wherein said conductor pair combinations further comprise pairings of said conductors with an additional conductive path or an earth ground.

3. The method of claim 1 further comprising the step of automatically identifying any balanced conductor pairs in said conductor pairs specified by said switching matrix by calculating a figure of merit for each conductor pair.

4. The method of claim 3 wherein said test is only performed on said balanced conductor pairs.

5. The method of claim 1 further comprising the step of mathematically comparing said test data with said analyzer to identify line anomalies.

6. The method of claim 1 wherein said test further comprises at least one of a non-linear junction detection operation a frequency or time domain reflectometry operation, a current test, a voltage test, a resistance test, an audio test or a video test.

7. A device for examining a multiple conductor cable to detect line anomalies, said device comprising:
software or circuitry for determining a set of possible conductor pairs for said multiple conductor cable;
software or coupling circuitry for selectively coupling said device to each pair of said conductors in said set of possible conductor pairs;
software or circuitry for performing a line test on each pair of conductors in said set of possible conductor pairs to obtain test data; and
a memory for selectively storing and recalling said test data.

8. The device of claim 7 further comprising a tabular or graphic display for displaying said test data.

9. The device of claim 8 wherein said display simultaneously displays test data from each pair of conductors in said set of conductor pairs.

10. The device of claim 7 further comprising software for mathematically comparing test data from each of said conductor pairs to identify line anomalies.

11. The device of claim 7 further comprising software or circuitry for identifying twisted or adjacent conductor pairs in said set of conductor pairs.

12. The device of claim 7 further comprising software or circuitry for recording and displaying a signal level detected on said pairs of conductors in said set of conductor pairs over a test interval.

13. The device of claim 7 further comprising software or circuitry for performing a non-linear junction or frequency or time domain reflectometry operation on each of said conductor pairs in said set of conductor pairs.

14. The device of claim 7 further comprising software and circuitry for performing at least one of a current, voltage test, resistance test, audio or video test on each of said conductor pairs in said set of conductor pairs.

15. The device of claim 7 wherein said possible conductor pairs include pairings of said conductors with an addition electrical conductor or an earth ground.

16. A line analyzer for detecting line anomalies on a multiple conductor cable having a plurality of wires, said line analyzer comprising:
pair selection circuitry for automatically identifying possible wire pairings of said plurality of wires of said multiple conductor cable;
switching circuitry for automatically and sequentially coupling said line analyzer to each of said possible wire pairings; and
test circuitry for performing a test on each of said possible wire pairs.

17. The line analyzer of claim 16 wherein said test further comprised a non-linear junction detection operation or a frequency or time domain reflectometry operation.

18. The line analyzer of claim 16 further comprising a graphic displaying for simultaneously displaying test data from each of said possible wire pairs.

19. The line analyzer of claim 16 further comprising balanced pair identification software or circuitry for identifying wire pairs in said possible wire pairs that are balanced in a twisted cable or adjacent in a flat cable.

20. The line analyzer of claim 16 further comprising software for mathematically comparing test results for each of said possible wire pairs.
